(19) United States
(12) Patent Application Publication
(10) Pub. No.: US 2011/0189855 A1
(43) Pub. Date: Aug. 4, 2011

(54) METHOD FOR CLEANING SURFACE CONTAINING Cu

(76) Inventors: Jen-Chieh Lin, Kaohsiung City (TW); Kai-Chun Yang, Tainan County (TW); Chih-Yueh Li, Taipei City (TW); Geng-Yu Fan, Tainan County (TW); Jeng-Yu Fang, Taipei County (TW); Teng-Chun Tsai, Tainan City (TW); Chia-Lin Hsu, Tainan City (TW)

(21) Appl. No.: 12/699,071

(22) Filed: Feb. 3, 2010

(51) Int. Cl. H01L 21/306

(52) U.S. Cl. 438/692; 257/E21.23

(57) ABSTRACT

A method for cleaning a surface is disclosed. First, a substrate including Cu and a barrier layer is provided. Second, a first chemical mechanical polishing procedure is performed on the substrate. Then, a second chemical mechanical polishing procedure is performed on the barrier layer. The second chemical mechanical polishing procedure includes performing a main chemical mechanical polishing procedure to partially remove the barrier layer and performing a chemical buffing procedure on the substrate using a chemical solution which has a pH value of about 6 to about 8 to remove residues on the substrate after the main chemical mechanical polishing procedure. Later, a water rinsing procedure is performed on the substrate. Afterwards, a post clean procedure is performed on the substrate after the second chemical mechanical polishing procedure.

### BACKGROUND OF THE INVENTION

1. Field of the Invention

The present invention generally relates to a method for cleaning a surface including Cu. In particular, the present invention is directed to a method for cleaning a surface including Cu by means of a chemical buffing procedure on a substrate using a specially formulated chemical solution which has a pH value approximately between 6 and 8 to remove undesirable residues on the substrate after a main chemical mechanical polishing procedure in order to facilitate a post clean procedure which is later performed on the substrate.

2. Description of the Prior Art

Because Cu has lower electrical resistance than Al, the techniques to form circuits in a semiconductor wafer have changed from etching a bulky conductive material to depositing a conductive material into pre-determined vias and/or trenches. This is generally known as the “damascene method”.

The advantages of Cu damascene method reside in a lower resistance capacitance (RC) delay due to higher electrical conductivity of Cu and its superior electro-migration performance, compared with Al. After the deposition procedure filling the pre-determined vias and trenches, the damascene method in later steps further involves removing superfluous metal by using a chemical mechanical polishing (CMP) for field Cu and barrier removal. Standard Cu CMP process involves two steps. The first one polishes Cu and stops on the barrier layer. The second one requires further removal of the underlying barrier layer and planarization of the entire surface. In some cases, benzotriazole (BTA) and its derivatives such as benzotriazole-5-carboxylic acid, 5-methyl-1H-benzotriazole are used as an inhibitor to facilitate Cu removal. This formulation indeed demonstrates a high planarization efficiency. After the CMP process, the substrate is subject to a post-clean step to completely remove all the residues on the surface.

The high planarization efficiency of this formulation is theoretically based on the formation of a strong BTA-Cu complex located on the surface of the substrate during polishing. Unfortunately, the formation of the strong BTA-Cu complex on the surface also inevitably inhibits the hydrophilic property of the surface of the substrate, and as a result impedes the following post-clean step in order to completely remove all the residues on the surface of the substrate. In the presence of a strong BTA-Cu complex on the surface of the substrate, the relatively hydrophobic surface of the substrate makes the workload of the post-clean step heavy or impossible. In other words, in such a way the post-clean step highly possibly fails to completely remove all the residues on the surface of the substrate as expected. Consequently, the failure of the post-clean step eventually jeopardizes the quality and yield of the semiconductor wafers.

Accordingly, a novel method for cleaning a surface including Cu is still needed to solve the problems in this field and to improve the quality and yield of the semiconductor wafers as well.

### SUMMARY OF THE INVENTION

The present invention therefore proposes a novel method for cleaning a surface including Cu. The method of the present invention on one hand may solve the problems as described above, and on the other hand the method of the present invention may also improve the quality and yield of the semiconductor wafers.

The present invention proposes a method for cleaning a surface. First, a substrate including Cu and a barrier layer is provided. Second, a first chemical mechanical polishing procedure is performed on the substrate to partially remove Cu. Then, a second chemical mechanical polishing procedure is performed on the substrate. The second chemical mechanical polishing procedure includes at least two steps. The first step is to perform a main chemical mechanical polishing procedure on the substrate to partially remove the barrier layer. The second step is to perform a chemical buffing procedure on the substrate. A chemical solution which has a pH value around 6 to 8 may be used in the second step to remove undesirable residues on the substrate after the main chemical mechanical polishing procedure. Later, a water rinsing procedure is performed on the substrate. Afterwards, a post clean procedure is performed on the substrate after the second chemical mechanical polishing procedure. Optionally, before the second chemical mechanical polishing procedure, a pre-clean procedure which uses the chemical solution may be performed on a polishing pad which is for use in the second chemical mechanical polishing procedure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for cleaning a surface including Cu of the present invention.

FIG. 8 shows the normalized defect counts vs. the method of the present and vs. the traditional method.

### DETAILED DESCRIPTION

The present invention provides a novel method for cleaning a surface including Cu, preferably for use in a damascene method. The method of the present invention in one aspect may substantially completely remove all the undesirable residues on the surface, and on the other hand the method of the present invention may also facilitate the following post-clean step to completely remove all the residues on the surface of the substrate as expected.

FIGS. 1-7 illustrate a method for cleaning a surface including Cu of the present invention. As shown in FIG. 1, firstly a substrate 101 is provided. The substrate 101 for example includes a damascene structure 102. The substrate 101 of the damascene structure 102 may have a copper layer 110 and an underlying barrier layer 120. Optionally, the damascene structure 102 may be a single damascene structure or a dual damascene structure. As a result, damascene structure 102 includes at least one of a via 103 and a trench 104. The barrier layer 120 may include Ta or TaN. In addition, there may be a cap layer 105 disposed within the substrate 101. The barrier layer 120 may be further in direct contact with a conductive layer 106. The conductive layer 106 may be part of the electrical connection of a source (not shown), a drain (not shown) and/or wires (not shown).

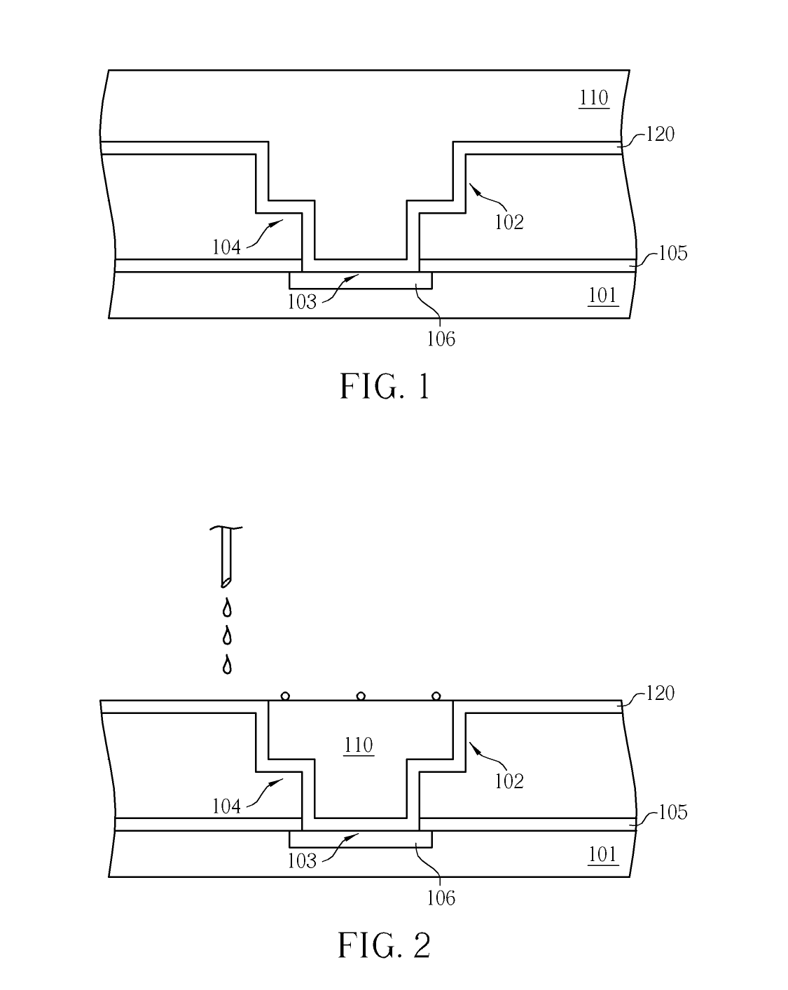

Then, as shown in FIG. 2, a first chemical mechanical polishing procedure is performed on the substrate 101. The purpose of the first chemical mechanical polishing procedure is mainly on the copper layer 110 for removing excess copper. Usually, during the CMP procedure the substrate 101 is placed on a polishing pad (not shown) to carry out a CMP. As described earlier, to facilitate the removal of excess copper, a chemical formulation containing benzotriazole (BTA) and its derivatives is usually employed. If the chemical formulation containing benzotriazole (BTA) and its derivatives is employed, the formation of a strong BTA-Cu complex during the polishing procedure happens on the surface of the copper layer. The first chemical mechanical polishing procedure is known to persons of ordinary skills in this art and the details will not be discussed.

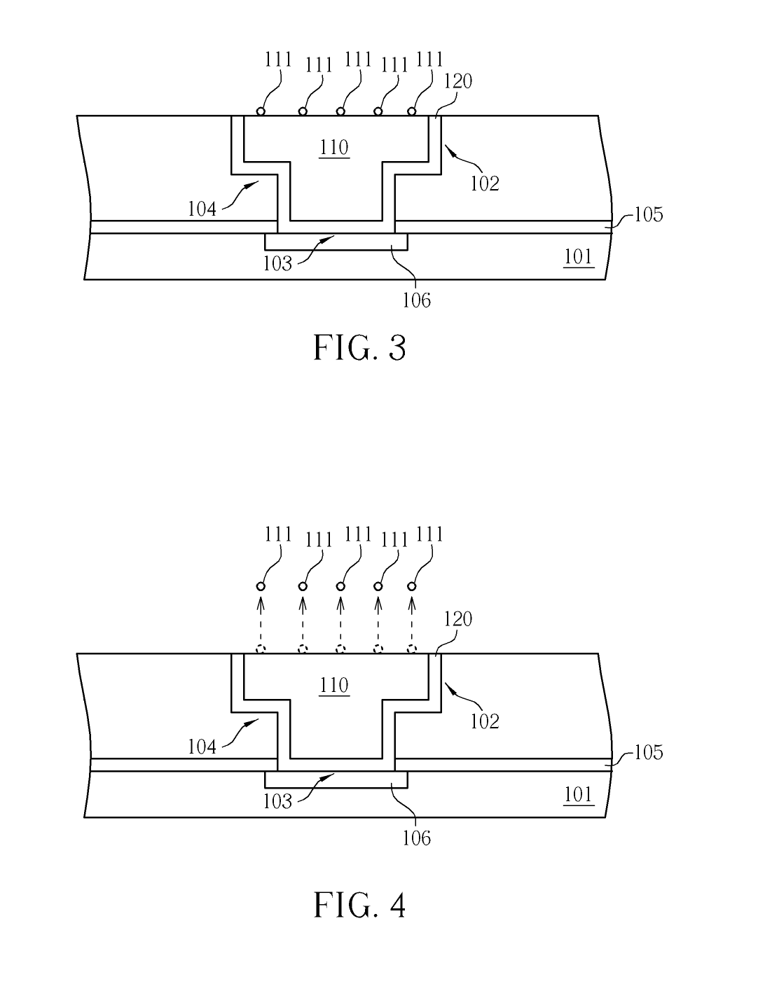

Later, as shown in FIG. 3, a second chemical mechanical polishing procedure should be carried out. The second chemical mechanical polishing procedure may include at least two steps. The first step, which is called a main chemical mechanical polishing procedure, is carried out on the substrate 101 in order to partially remove the barrier layer 120. This step is believed to selectively remove part of the barrier layer 120. The main chemical mechanical polishing procedure is known to persons of ordinary skills in this art and the details will not be discussed. There may be some undesirable residues 111, such as abrasives or complex, left on the surface of the substrate 101.

The second step, as shown in FIG. 4, which is called a chemical buffing procedure, is carried out on the substrate 101 after the main chemical mechanical polishing procedure. The main purpose of the chemical buffing procedure is directed to remove most of undesirable residues 111, such as abrasives or complex, left on the surface of the substrate 101. The chemical buffing procedure may be carried out for about 5 seconds to about 15 seconds. Both the main chemical mechanical polishing procedure and the chemical buffing procedure are part of the CMP procedure carried out on the substrate 101. Please notice that the main chemical mechanical polishing procedure and the chemical buffing procedure are supplied with different slurries or solutions.

For example, if the chemical formulation containing benzotriazole (BTA) and its derivatives is employed in the first chemical mechanical polishing procedure, it is believed that a strong BTA-Cu complex is formed on the surface of the copper layer during the procedure. This BTA-Cu complex residue potentially jeopardizes the hydrophilic property of the surface of the substrate 101 and makes the following water rinsing procedure and the post clean procedure difficult or impossible to achieve the predetermined purposes. In other words, the chemical buffing procedure may increase the hydro-affinity of the substrate 101 as well.

The second step uses a specially formulated chemical solution to facilitate and to remove most of undesirable residues left on the surface of the substrate 101. The specially formulated chemical solution generally has a mild pH range, about 6 to about 8 for example. Further, the specially formulated chemical solution may have various ingredients, for example at least one of an oxidizing agent, an organic amine, a chelating agent, a corrosion inhibitor and an amino acid.

For example, the oxidizing agent may be hydrogen peroxide. The organic amine may be a water-soluble or water-miscible organic amine or imine. The chelating agent may be at least one 1,3-dicarbonyl compound. The amino acid may be molecules containing an amine group, a carboxylic acid group and a side chain of different chemical functions, such as an alpha-amino acid. As known to persons of ordinary skills in the art, the specially formulated chemical solution may be optionally a concentrated solution or a diluted solution. The concentration of the chemical solution is at the discretion of persons of ordinary skills in the art when the chemical solution is used. The specially formulated chemical solution may be originally a concentrated solution with or without an organic solvent, or with or without water for the convenience of transportation or long term storage. Water or at least one organic solvent may be added into the specially formulated chemical solution to obtain a desirable concentration.

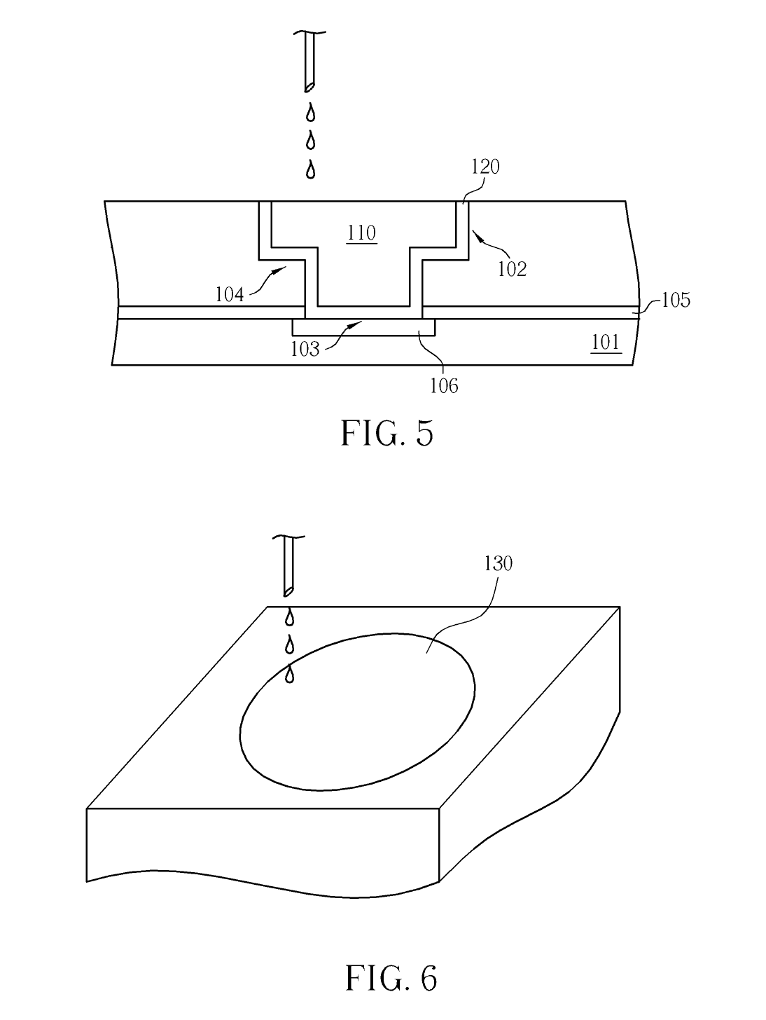

After the second chemical mechanical polishing procedure, as shown in FIG. 5, a water rinsing procedure is carried out on the substrate 101. Both the water rinsing procedure as well as the chemical buffing procedure are part of the barrier CMP. DI water is preferred in the water rinsing procedure to primarily wash off some of the residues or chemicals on the surface of the substrate 101.

Optionally, before the following procedure, a pre-clean procedure may be carried out, as shown in FIG. 6. The polishing pad 130 which is for use in the second chemical mechanical polishing procedure is subject to the treatment in the pre-clean procedure. Preferably, the pre-clean procedure uses the same or similar chemical solution used in the following second chemical mechanical polishing procedure to primarily wash the polishing pad in advance. The pre-clean procedure may be carried out for about 5 seconds to about 15 seconds.

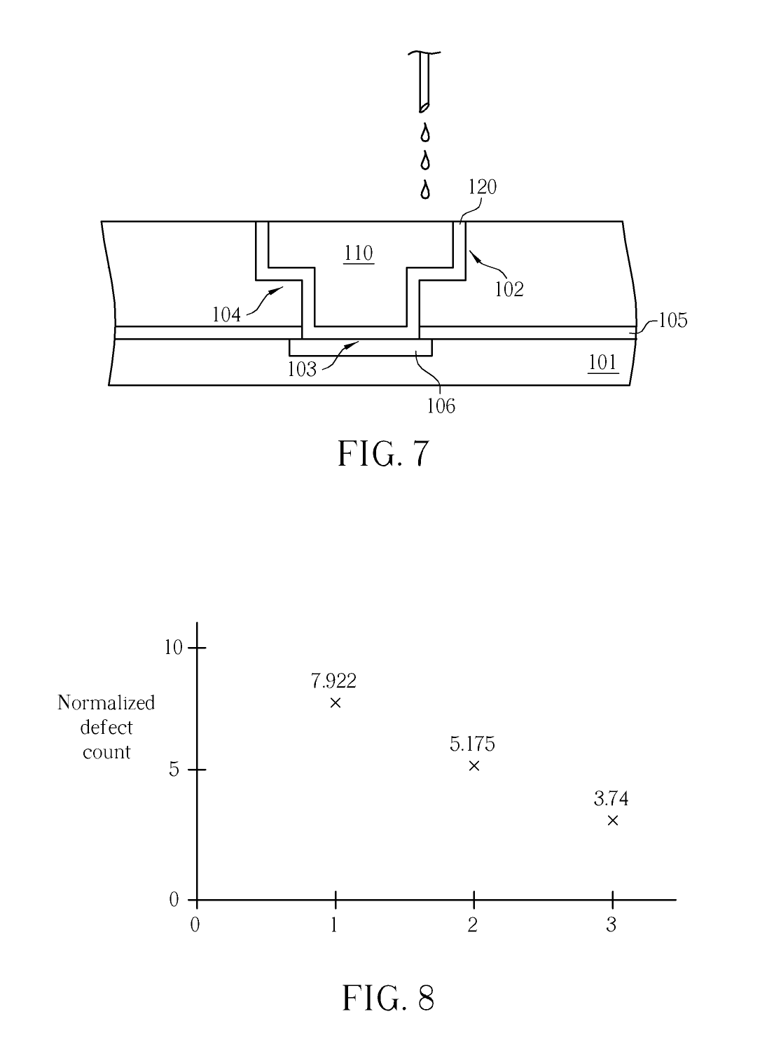

Afterwards, as shown in FIG. 7, a post clean procedure is carried out on the substrate 101 after the second chemical mechanical polishing procedure in order to thoroughly remove contaminants on the substrate 101 and to obtain a clean substrate surface. Usually, during the post clean procedure the substrate 101 is removed from a polishing pad to carryout the post clean procedure. The post clean procedure is known to persons of ordinary skills in this art and the details will not be discussed.

FIG. 8 shows the normalized defect count vs. different methods, such as a method without a pre-clean procedure and without a chemical buffing procedure (conventional) 1, a method without a pre-clean procedure and with a chemical buffing procedure 2 as well as a method with both a pre-clean procedure and a chemical buffing procedure 3. The results show that the method of the present invention with or without a pre-clean procedure has lower defect counts than the traditional method, although the method of the present invention with a pre-clean procedure has even lower defect counts.

Those skilled in the art will readily observe that numerous modifications and alterations of the device and method may be made while retaining the teachings of the invention.

What is claimed is:

1. A method for cleaning a surface comprising Cu, comprising:
providing a substrate comprising Cu and a barrier layer;
performing a first chemical mechanical polishing procedure on said substrate;
performing a second chemical mechanical polishing procedure on said barrier layer, comprising:
performing a main chemical mechanical polishing procedure to partially remove said barrier layer;
performing a chemical buffing procedure on said substrate using a chemical solution to remove residues on said substrate after said main chemical mechanical polishing procedure, wherein said chemical solution has a pH value of about 6 to about 8; and
performing a water rinsing procedure on said substrate; and
performing a post clean procedure on said substrate after said second chemical mechanical polishing procedure.

2. The method of claim 1, further comprising:
performing a pre-clean procedure using said chemical solution on a polishing pad which is for use in said second chemical mechanical polishing procedure, before said second chemical mechanical polishing procedure.

3. The method of claim 2, wherein said pre-clean procedure is carried out for about 5 seconds to about 15 seconds.

4. The method of claim 1, wherein said first chemical mechanical polishing procedure polishes Cu.

5. The method of claim 1, wherein said residues comprise at least one of benzotriazole (BTA) and its derivative.

6. The method of claim 1, wherein said chemical solution is a concentrated solution.

7. The method of claim 1, wherein said chemical solution is a dilute solution.

8. The method of claim 1, wherein said chemical solution comprises at least one of an oxidizing agent, an organic amine, a chelating agent, a corrosion inhibitor and an amino acid.

9. The method of claim 8, wherein said oxidizing agent comprises hydrogen peroxide.

10. The method of claim 8, wherein said organic amine comprises a water-soluble organic amine.

11. The method of claim 8, wherein said organic amine comprises a water-miscible organic amine.

12. The method of claim 8, wherein said chelating agent comprises at least one 1,3-dicarbonyl compound.

13. The method of claim 8, wherein said amino acid comprises an alpha-amino acid.

14. The method of claim 8, wherein said chemical solution further comprises an organic solvent.

15. The method of claim 8, wherein said chemical solution further comprises an imine.

16. The method of claim 1, wherein said chemical buffing procedure is carried out for about 5 seconds to about 15 seconds.

17. The method of claim 1, wherein said chemical buffing procedure increases the hydro-affinity of said substrate.

18. The method of claim 1, wherein said chemical buffing procedure removes abrasives on said substrate.
